(19) United States
(12) Patent Application Publication
(10) Pub. No.: US 2022/0108931 A1
(43) Pub. Date: Apr. 7, 2022

(54) SEMICONDUCTOR PACKAGE, SEMICONDUCTOR DEVICE, AND METHOD FOR MANUFACTURING SEMICONDUCTOR DEVICE

(71) Applicant: SUMITOMO ELECTRIC DEVICE INNOVATIONS, INC., Kanagawa (JP)

(72) Inventor: Takashi KITAWADA, Yokohama-shi (JP)

(73) Assignee: SUMITOMO ELECTRIC DEVICE INNOVATIONS, INC., Kanagawa (JP)

(21) Appl. No.: 17/552,231

(22) Filed: Dec. 15, 2021

Related U.S. Application Data
(62) Division of application No. 16/814,576, filed on Mar. 10, 2020.

(30) Foreign Application Priority Data
Mar. 12, 2019 (JP) 2019-044587

(51) Int. Cl. H01L 23/043; H01L 23/498; H01L 21/52; H01L 21/48; H01L 23/00

(52) U.S. Cl. CPC H01L 23/043; H01L 23/49844; H01L 24/29; H01L 21/4867; H01L 21/52

(57) ABSTRACT

A method for manufacturing a semiconductor device includes forming a lead frame assembly in which a first side wall portion and a second side wall portion, both made of a resin, are joined to each other in a state of having a metal lead frame sandwiched therebetween; applying a sintering metal paste to a disposition region of the lead frame assembly and disposing the lead frame assembly on the sintering metal paste; and sintering the sintering metal paste between a metal base of the semiconductor device and the lead frame assembly to join the base and the lead frame assembly to each other.

### CROSS-REFERENCE TO RELATED APPLICATIONS

This application is based upon and claims the benefit of priority from Japanese Patent Application No. 2019-044587, filed on Mar. 12, 2019, the entire contents of which are incorporated herein by reference.

### TECHNICAL FIELD

The present disclosure relates to a semiconductor package, a semiconductor device, and a method for manufacturing a semiconductor device.

### BACKGROUND

JP2011-165931A discloses a high-frequency circuit module. This module includes first and second printed boards. High-frequency components are mounted on the first printed board. In a part of the second printed board facing a mounting region of the high-frequency components, an embedment wall surface for a plurality of conductor vias and a groove of which the circumference is surrounded by a conductor layer that is an outer layer or an inner layer are provided. Outer layer patterns of the first and second printed boards facing each other are electrically connected to each other through soldering. The high-frequency components are accommodated inside a groove space of the second printed board.

JP H10-163353A discloses a package for a microwave device. This package includes a base metal serving as a grounding electrode, and three ceramic layers provided thereon. In a ceramic layer (lowermost layer), a ground conductive pattern for a microstrip line is provided. In a ceramic layer (intermediate layer), a line conductive pattern electrically connecting an external circuit and a semiconductor chip to each other is provided. In a ceramic layer (uppermost layer), a ground conductive pattern connected to the base metal is provided. In the vicinity of a region in which a lead terminal is formed, the ground conductive pattern of the ceramic layer (lowermost layer) is not exposed from a lamination end portion.

### SUMMARY

The present disclosure provides a semiconductor package comprising a metal base, a side wall, and at least one metal lead. The metal base has a main surface configured to mount at least one semiconductor element thereon. The side wall has a frame shape and is disposed on the main surface of the metal base. The side wall includes a first side wall portion made of a resin, and a second side wall portion made of a resin. The second side wall portion is placed on the first side wall portion and is joined to the first side wall portion with an adhesive. The metal lead is partially sandwiched between the first side wall portion and the second side wall portion. A first end of the metal lead is exposed inside of the side wall, and a second end of the metal lead is located outside of the side wall. The second end is opposite to the first end.

The present disclosure provides a semiconductor device. The semiconductor device comprises the above semiconductor package, and at least one semiconductor element disposed on the main surface of the metal base inside the side wall.

The present disclosure provides a method for manufacturing a semiconductor device. The semiconductor device includes a metal base having a main surface to mount a semiconductor element thereon, and a side wall joined to the main surface of the metal base and surrounding the semiconductor element. The method comprises: (a) forming a lead frame assembly in which a first side wall portion made of a resin constituting a part of the side wall adjacent to the main surface and a second side wall portion made of a resin constituting a remaining part of the side wall opposite to the main surface are joined to each other in a state of having a metal lead frame sandwiched therebetween; (b) applying a sintering metal paste to a disposition region of the lead frame assembly on the main surface of the base and disposing the lead frame assembly on the sintering metal paste; and (c) sintering the sintering metal paste between the metal base and the lead frame assembly to join the base and the lead frame assembly to each other.

### BRIEF DESCRIPTION OF THE DRAWINGS

The foregoing and other purposes, aspects and advantages will be better understood from the following detailed description of embodiments of the disclosure with reference to the drawings, in which:

FIG. 1 is a perspective view of a package for a semiconductor device according to a first embodiment.

FIG. 2 is a plan view of the package for a semiconductor device illustrated in FIG. 1.

FIG. 3 is a cross-sectional view of the package along line III-III in FIG. 2.

FIG. 4 is a cross-sectional view of the package along line IV-IV in FIG. 2.

FIG. 5 is a cross-sectional view of the package along line V-V in FIG. 2.

FIG. 6A is a plan view of a first side wall portion, and FIG. 6B is a plan view of a second side wall portion.

FIG. 7 is a plan view illustrating the semiconductor device including the package.

FIG. 8 is a view illustrating a front surface of a semiconductor die.

FIG. 9 is a view illustrating a rear surface of the semiconductor die.

FIGS. 10A and 10B are views for describing a method for manufacturing the package and the semiconductor device.

FIG. 11 is a view for describing the method for manufacturing the package and the semiconductor device.

FIGS. 12A and 12B are views for describing the method for manufacturing the package and the semiconductor device.

FIG. 13 is a view for describing the method for manufacturing the package and the semiconductor device.

FIGS. 14A and 14B are views for describing the method for manufacturing the package and the semiconductor device.

FIGS. 15A and 15B are views for describing the method for manufacturing the package and the semiconductor device.

FIGS. 16A and 16B are views for describing the method for manufacturing the package and the semiconductor device.

FIG. 17 is a view illustrating a step according to a first modification example of the foregoing embodiment, showing a lead frame and an adhesive.

FIG. 18 is a view illustrating a step according to a second modification example of the foregoing embodiment, showing the second side wall part and the adhesive.

FIG. 19 is a view illustrating a step according to a third modification example of the foregoing embodiment, showing a lid portion and the adhesive.

FIGS. 20A and 20B are views illustrating each of steps in a manufacturing method according to a fourth modification example.

FIGS. 21A and 21B are views illustrating each of the steps in the manufacturing method according to the fourth modification example.

FIGS. 22A and 22B are views illustrating each of the steps in the manufacturing method according to the fourth modification example.

FIGS. 23A and 23B are views illustrating each of the steps in the manufacturing method according to the fourth modification example.

FIGS. 24A and 24B are views illustrating each of the steps in the manufacturing method according to the fourth modification example.

FIGS. 25A and 25B are views illustrating each of the steps in the manufacturing method according to the fourth modification example.

FIGS. 26A and 26B are views illustrating each of the steps in the manufacturing method according to the fourth modification example.

### DETAILED DESCRIPTION

### Problem to be Solved by the Present Disclosure

A package for air-tightly sealing a semiconductor element is used in semiconductor devices for high frequencies. The package includes a base having a metal main surface, a side wall of a dielectric substance having a bottom surface joined to the main surface of the base, and a metal lead joined to an upper surface of the side wall opposite to the bottom surface. For electrical connection between an external circuit of the semiconductor device and the semiconductor element, the metal lead extends from the upper surface of the side wall to a side of the package.

In such packages in the related art, a ceramic is often used as a material of a side wall. A ceramic side wall has higher reliability than other materials such as a resin and can firmly support a lead. However, it is difficult to mold a ceramic compared to other materials such as a resin. In contrast, when a resin is used as a material of the side wall, there is an advantage that molding can be performed easily and a manufacturing step can be simplified. On the other hand, in respect of strength, a resin is inferior to a ceramic. When a resin side wall has a shape similar to a ceramic side wall, such a resin side wall may not be able to support a lead firmly. Thus, a resin side wall is limited to a case or the like of using a flexible board (FPC) which requires no support strength, in place of a metal lead.

### Effect of the Present Disclosure

According to the present disclosure, a metal lead of a semiconductor package can be firmly supported using a resin side wall.

### DESCRIPTION OF EMBODIMENTS OF THE PRESENT DISCLOSURE

Embodiments of the present disclosure will be listed and described. A semiconductor package according to one embodiment comprises a metal base, a side wall, and at least one metal lead. The metal base has a main surface configured to mount at least one semiconductor element thereon. The side wall has a frame shape and is disposed on the main surface of the metal base. The side wall includes a first side wall portion made of a resin, and a second side wall portion made of a resin. The second side wall portion is placed on the first side wall portion and is joined to the first side wall portion with an adhesive. The metal lead is partially sandwiched between the first side wall portion and the second side wall portion. A first end of the metal lead is exposed inside of the side wall, and a second end of the metal lead is located outside of the side wall. The second end is opposite to the first end.

In one embodiment, the adhesive may include a thermosetting resin. The adhesive may include a thermosetting epoxy resin. The first side wall portion and the second side wall portion may include epoxy resins.

In one embodiment, at least one of the first side wall portion and the second side wall portion may be provided with at least one pair of holes each passing through the wall portion in a thickness direction thereof. The metal lead may include at least one pair of projections each extending along the thickness direction and being inserted into the pair of holes, respectively. The thickness direction is a direction facing an upper surface of the side wall and the main surface of the metal base to each other.

In one embodiment, at least one of the first side wall portion and the second side wall portion may be provided with a recess depressed along a thickness direction of the side wall portion. The sandwiched part of the metal lead may be placed within the recess. In this embodiment, the first side wall portion may be provided with the recess depressed toward the main surface of the metal base. In this embodiment, the first end of the metal lead may be placed within the recess to being exposed inside of the side wall.

In one embodiment, the second side wall portion may be provided with a depressed portion depressed along a direction from an inner surface of the side wall toward an outer surface of the side wall. The first end of the metal lead may be exposed from the depressed portion.

In one embodiment, the first side wall portion may be joined to the metal base with a joining material including a sintering metal paste.

A semiconductor device according to one embodiment comprises the semiconductor package according to any one of the above embodiments, and at least one semiconductor element disposed on the main surface of the metal base inside the side wall.

In one embodiment, the semiconductor element may be joined to the metal base through a joining material including a sintering metal paste. The semiconductor element may include a semiconductor die being a transistor including a source via, a gate electrode, and a drain electrode.

In one embodiment, the semiconductor device may further comprises a lid disposed on an upper surface, which is opposite to the main surface of the metal base, of the side wall. The lid may completely covers an opening of the side wall to air-tightly seal the semiconductor package.

In one embodiment, the at least one metal lead may include an input lead located at a first part of the side wall and an output lead located at a second part of the side wall opposite to the first part. The input lead may be connected to the semiconductor element and the semiconductor element may be connected to the output lead.

As one embodiment, a method for manufacturing a semiconductor device including a metal base having a main surface to mount a semiconductor element thereon, and a side wall joined to the main surface of the metal base and surrounding the semiconductor element, comprises (a) forming a lead frame assembly in which a first side wall portion made of a resin constituting a part of the side wall adjacent to the main surface and a second side wall portion made of a resin constituting a remaining part of the side wall opposite to the main surface are joined to each other in a state of having a metal lead frame sandwiched therebetween; (b) applying a sintering metal paste to a disposition region of the lead frame assembly on the main surface of the base and disposing the lead frame assembly on the sintering metal paste; and (c) sintering the sintering metal paste between the metal base and the lead frame assembly to join the base and the lead frame assembly to each other.

In one embodiment of the manufacturing method, the forming of the lead frame assembly may further include: (a1) bending a projection formed in the lead frame in a thickness direction of the lead frame, and (a2) sandwiching the lead frame between the first side wall portion and the second side wall portion while the projection is inserted into a hole formed in the first side wall portion or the second side wall portion.

In one embodiment of the manufacturing method, at least one of the first side wall portion and the second side wall portion may include a recess configured to receive the lead frame on a surface facing the lead frame.

In one embodiment, in the forming of the lead frame assembly, the first side wall portion, the lead frame, and the second side wall portion may be joined to each other using a thermosetting resin.

In one embodiment, in the applying of the sintering metal paste, the sintering metal paste may be further applied to a disposition region of the semiconductor element on the main surface of the metal base, and the semiconductor element may be disposed on the sintering metal paste. In the sintering of the sintering metal paste, the sintering metal paste between the metal base and the semiconductor element may be sintered such that the metal base and the semiconductor element are joined to each other.

### DETAILED DESCRIPTION OF THE EMBODIMENTS OF THE PRESENT DISCLOSURE

Specific examples of a package for a semiconductor device, a semiconductor device, and a method for manufacturing a semiconductor device according to the present disclosure will be described below with reference to the drawings. The present invention is not limited to these examples. The present invention is indicated by the claims, and it is intended to include all changes within meanings and a range equivalent to the claims. In the following description, the same reference signs are applied to the same elements in description of the drawings, and overlapping description will be omitted.

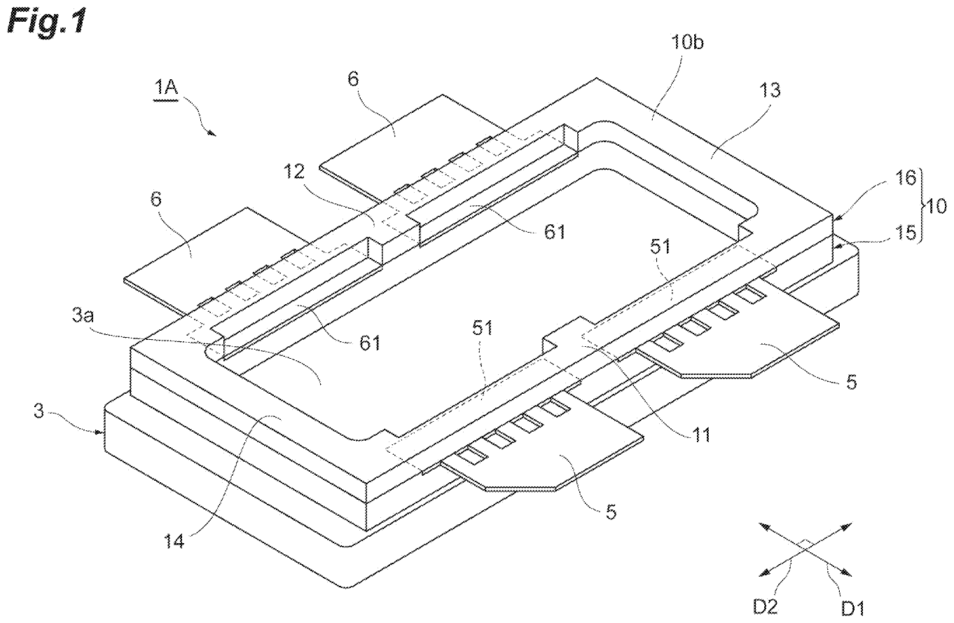

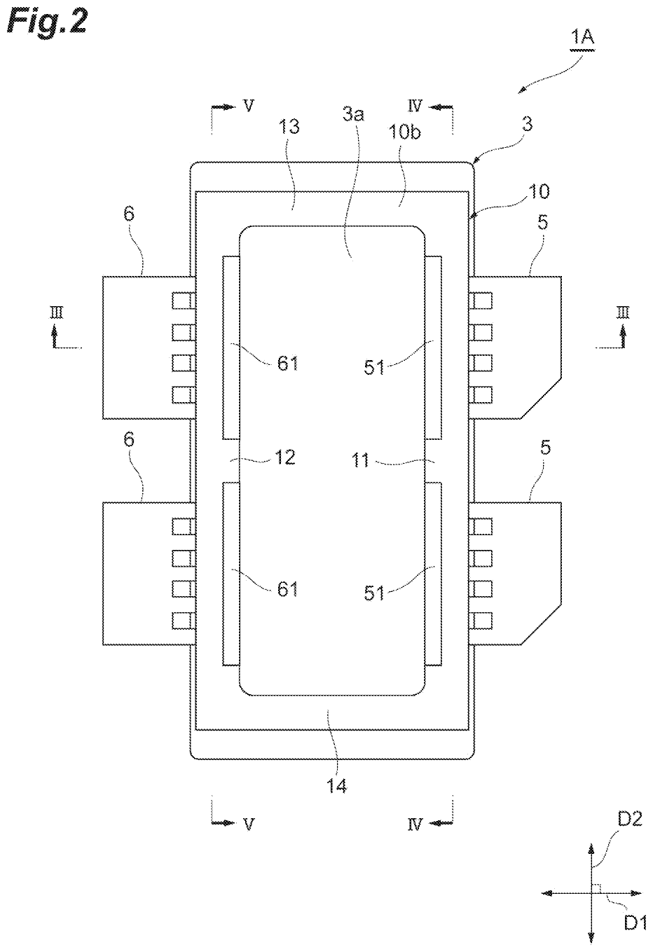

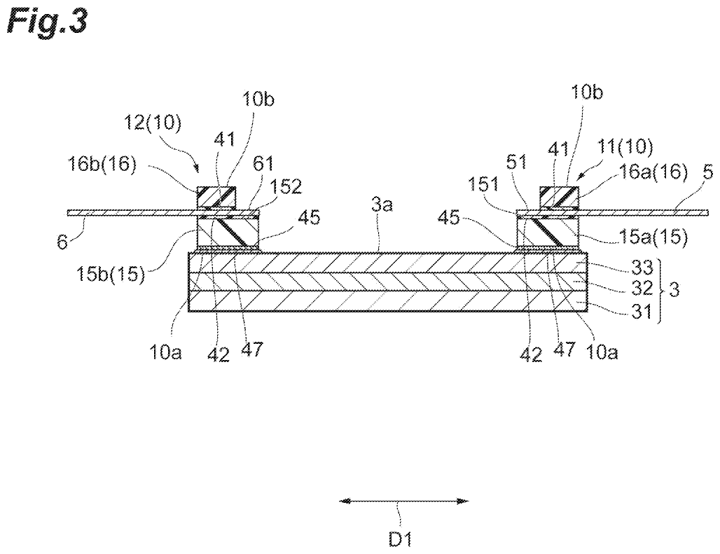

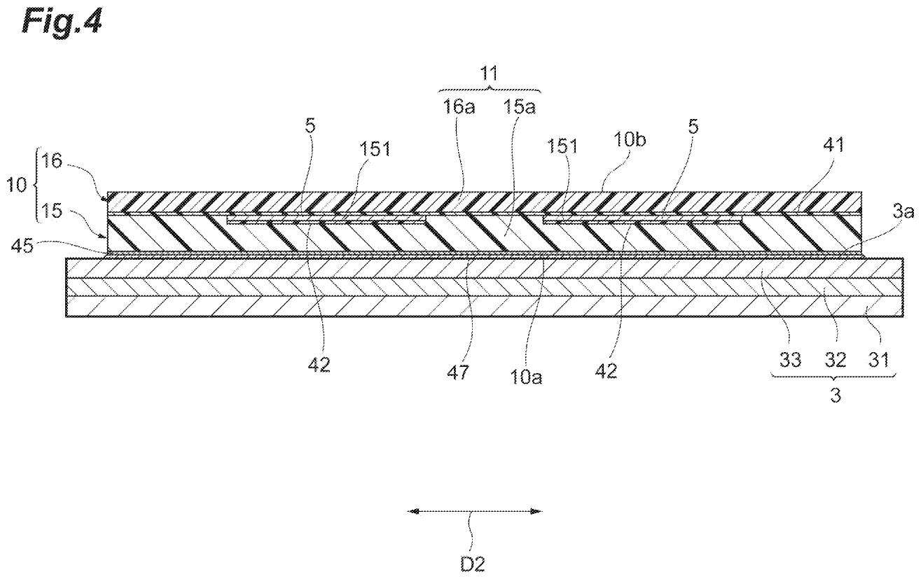

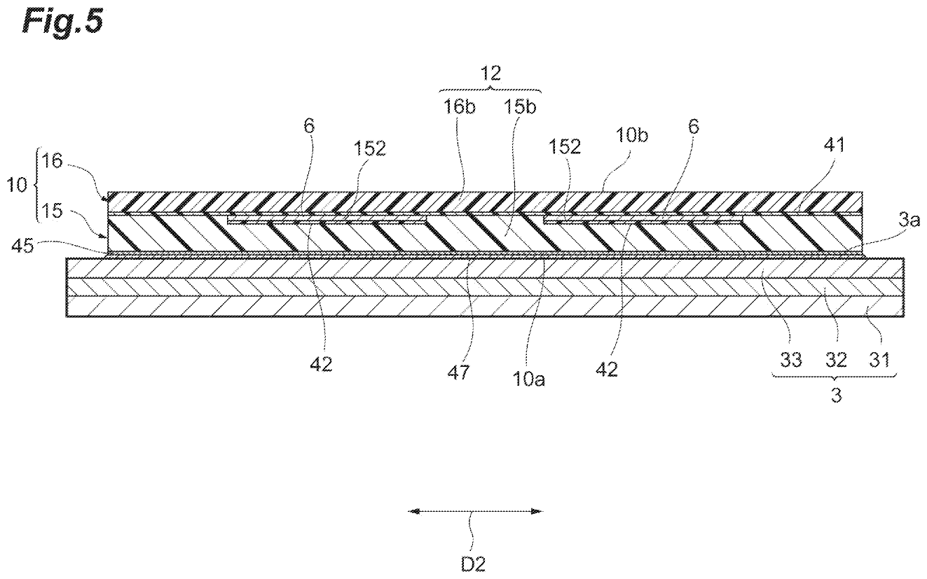

FIG. 1 is a perspective view of a package 1A for a semiconductor device according to a first embodiment. FIG. 2 is a plan view of the package 1A. FIG. 3 is a cross-sectional view of the package 1A along line III-III in FIG. 2. FIG. 4 is a cross-sectional view of the package 1A along line IV-IV in FIG. 2. FIG. 5 is a cross-sectional view of the package 1A along line V-V in FIG. 2. In these diagrams, illustration of a lid portion (cap) is omitted. As illustrated in these diagrams, the package 1A of the present embodiment includes a base 3, two input leads 5, two output leads 6, and a side wall 10.

The base 3 is a plate-shaped member having a flat metal main surface 3a. For example, the base 3 is formed of copper, an alloy of copper and molybdenum, or an alloy of copper and tungsten; or a lamination material formed of a copper plate, a molybdenum plate, a tungsten plate, an alloy plate of copper and molybdenum, or an alloy plate of copper and tungsten. In the examples illustrated in the diagrams, the base 3 has a structure in which an alloy plate 32 of copper and molybdenum is sandwiched between two copper plates 31 and 33. A front surface of a base material of the base 3 is subjected to plating of nickel chrome (nichrome, NiCr)-gold, nickel (Ni)-gold, nickel-palladium-gold, -silver, or -nickel, or nickel-palladium. Gold, silver, and palladium are plating materials, and NiCr, Ni, and the like are seed materials. Adhesion can be enhanced in a case of including a plating material and a seed material compared to a case of including only a plating material. For example, the thickness of the base 3 is within a range of 0.5 mm to 1.5 mm. For example, the planar shape of the base 3 is a rectangular shape having a direction D2 along the main surface 3a as a longitudinal direction.

The side wall 10 is a substantially rectangular frame shaped-member. As illustrated in FIG. 1, the side wall 10 has a pair of parts 11 and 12 facing each other along the main surface 3a of the base 3, and a pair of parts 13 and 14 facing each other. The parts 11 and 12 extend parallel to each other in the direction D2, and the parts 13 and 14 extend parallel to each other in a direction D1 intersecting (for example, orthogonal to) the direction D2. A cross section of each of the parts 11 to 14 perpendicular to an extending direction has a rectangular shape or a square shape. The height of the side wall 10 in a normal direction to the main surface 3a is within a range of 0.5 mm to 1.0 mm, for example.

The side wall 10 is constituted of a first side wall portion 15 and a second side wall portion 16. The first side wall portion 15 is made of a resin and constitutes a part of the side wall 10 adjacent to the main surface 3a. The second side wall portion 16 is made of a resin and constitutes the remaining part of the side wall 10 opposite to the main surface 3a. Resins constituting the first side wall portion 15 and the second side wall portion 16 are paper epoxy, glass epoxy, or the like generally used in printed circuit boards (PCBs), for example. The glass epoxy is a substance obtained by dipping glass fiber cloth in an epoxy resin and performing thermosetting treatment and may be called as flame retardant type 4 (FR 4). The thickness of the first side wall portion 15 is within a range of 0.5 mm to 2.0 mm and is 1.6 mm, as an example. The thickness of the second side wall portion 16 is within a range of 0.2 mm to 2.0 mm and is 0.7 mm, as an example.

The first side wall portion 15 is provided on the main surface 3a, and the second side wall portion 16 is provided on the first side wall portion 15. In other words, the first side wall portion 15 is positioned between the main surface 3a and the second side wall portion 16. The first side wall portion 15 and the second side wall portion 16 are joined to each other with an adhesive 41 interposed therebetween. The adhesive 41 is a thermosetting resin and is a thermosetting epoxy resin, as an example.

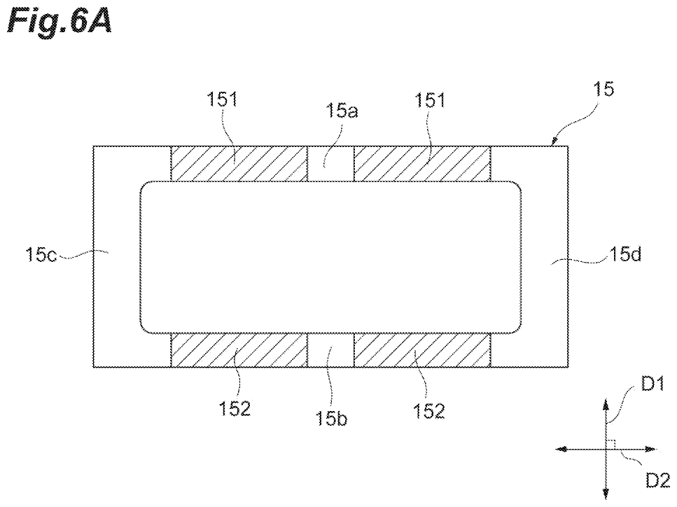

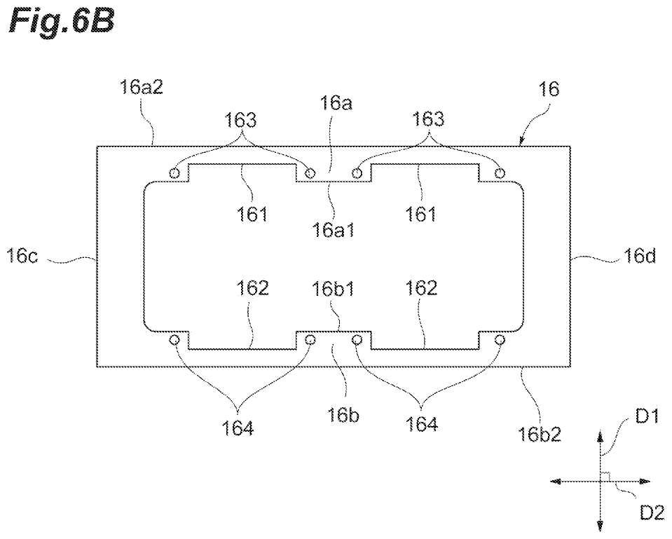

FIG. 6A is a plan view of the first side wall portion 15, and FIG. 6B is a plan view of the second side wall portion 16. Similar to the side wall 10, the planar shapes of the first side wall portion 15 and the second side wall portion 16 are substantially rectangular frame shapes. The first side wall portion 15 has a pair of parts 15a and 15b facing each other, and a pair of parts 15c and 15d facing each other. The parts 15a and 15b extend parallel to each other in the direction D2, and the parts 15c and 15d extend parallel to each other in the direction D1. Similarly, the second side wall portion 16 has a pair of parts 16a and 16b facing each other, and a pair of parts 16c and 16d facing each other. The parts 16a and 16b extend parallel to each other in the direction D2, and the parts 16c and 16d extend parallel to each other in the direction D1. The parts 15a and 16a constitute the part 12 of the side wall 10 described above. The parts 15b and 16b constitute the part 11 of the side wall 10. The parts 15c and 16c constitute the part 14 of the side wall 10. The parts 15d and 16d constitute the part 13 of the side wall 10.

The side wall 10 has a flat bottom surface 10a facing the main surface 3a of the base 3, and an upper surface 10b opposite to the bottom surface 10a. The bottom surface 10a is a surface of the first side wall portion 15 opposite to a surface facing the second side wall portion 16, and the upper surface 10b is a surface of the second side wall portion 16 opposite to a surface facing the first side wall portion 15. A metal film 45 is formed on the entire surface of the bottom surface 10a. The metal film 45 is s a metal film firmly fixed to the first side wall portion 15. The metal film 45 may be a film obtained by performing plating of Au or Ni on a Cu film. The bottom surface 10a is joined to the main surface 3a of the base 3 with the metal film 45 and a joining material 47 interposed therebetween. The joining material 47 is a sintering metal paste. For example, the sintering metal paste is a silver paste including a solvent and a silver filler having remarkably smaller particle sizes than particle sizes of a silver filler contained in a silver paste known in the related art. Joining using the sintering silver paste becomes metallic and sintered bonding between particles, including a phenomenon in which a fine silver filler is activated and sintering is performed at a relatively low temperature, thereby having excellent strength and long-term reliability.

The input leads 5 and the output leads 6 are metal plate-shaped members protruding outward from the side wall 10 and are thin metal plates of copper, a copper alloy, or an iron alloy, as an example. One end portions of the input leads 5 in the direction D1 are sandwiched between the part 15a of the first side wall portion 15 and the part 16a of the second side wall portion 16. Specifically, at least one of the first side wall portion 15 and the second side wall portion 16 (first side wall portion 15 in the illustrated example) has recesses 151 (refer to FIGS. 3 and 4) for respectively receiving the input leads 5 on surfaces facing the input leads 5. In FIG. 6A, presence ranges of the recesses 151 are indicated using hatching. The recesses 151 are depressed in a thickness direction of the first side wall portion 15. The input leads 5 are insulated with respect to the main surface 3a of the base 3 by the part 15a of the first side wall portion 15.

One end portions of the output leads 6 in the direction D1 are sandwiched between the part 15b of the first side wall portion 15 and the part 16b of the second side wall portion 16. Specifically, at least one of the first side wall portion 15 and the second side wall portion 16 (first side wall portion 15 in the illustrated example) has recesses 152 (refer to FIGS. 3 and 5) for respectively receiving the output leads 6 on surfaces facing the output leads 6. In FIG. 6A, presence ranges of the recesses 152 are indicated using hatching. The output leads 6 are insulated with respect to the main surface 3a of the base 3 by the part 15b of the first side wall portion 15.

The part 16a of the second side wall portion 16 has depressed portions 161 formed on an inner surface 16a1. The depressed portions 161 are depressed from the inner surface 16a1 toward an outer surface 16a2 and extend from a surface of the part 16a facing the input leads 5 to a surface (upper surface 10b) opposite thereto. The depressed portions 161 are provided at positions overlapping the input leads 5 when viewed in the thickness direction of the second side wall portion 16, and upper surfaces of one end portions 51 of the input leads 5 are exposed in these depressed portions 161 inside the package 1A (refer to FIGS. 1 and 2). Similarly, the part 16b of the second side wall portion 16 has depressed portions 162 formed on an inner surface 16b1. The depressed portions 162 are depressed from the inner surface 16b1 toward an outer surface 16b2 and extend from a surface of the part 16b facing the output leads 6 to a surface (upper surface 10b) opposite thereto. The depressed portions 162 are provided at positions overlapping the output leads 6, and upper surfaces of one end portions 61 of the output leads 6 are exposed in the depressed portions 162 inside the package 1A (refer to FIGS. 1 and 2).

Minute holes 163 penetrating the part 16a are formed in the vicinity of both ends of the depressed portion 161 in the extending direction (direction D2) of the part 16a. Projections (which will be described below) formed in the end portions of the input leads 5 are inserted into the holes 163. Similarly, minute holes 164 penetrating the part 16b are formed in the vicinity of both ends of the depressed portions 162 in the extending direction (direction D2) of the part 16b. Projections (which will be described below) formed in the end portions of the output leads 6 are inserted into the holes 164.

Each of one end portions of the input leads 5 and the output leads 6 is joined to the first side wall portion 15 with an adhesive 42 interposed therebetween. The adhesive 42 is a thermosetting resin and is a thermosetting epoxy resin, as an example. Each of one end portions of the input leads 5 and the output leads 6 is joined to the second side wall portion 16 with the adhesive 41 for joining the first side wall portion 15 and the second side wall portion 16 to each other interposed therebetween.

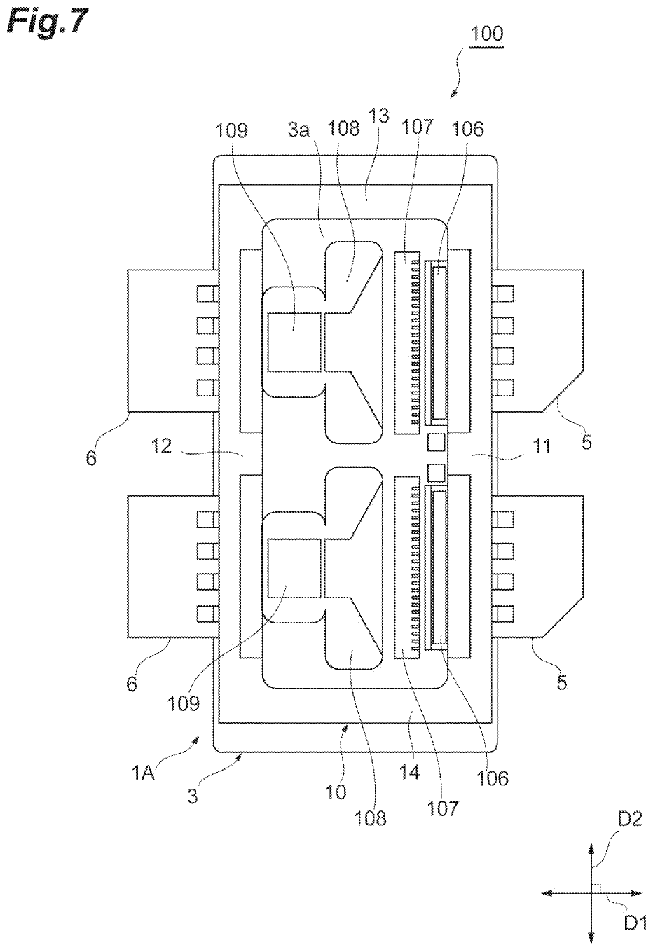

FIG. 7 is a plan view illustrating a constitution of a semiconductor device 100 including the package 1A of the present embodiment described above. FIG. 7 illustrates a state where the lid portion (cap) of the semiconductor device 100 is detached. This semiconductor device 100 includes input matching circuits 106, semiconductor dies 107 (semiconductor elements), output matching circuits 108, and output capacitors 109, in addition to the package 1A. The input matching circuits 106, the semiconductor dies 107, the output matching circuits 108, and the output capacitors 109 are accommodated in the package 1A and are mounted in a region surrounded by the side wall 10 on the main surface 3a of the base 3. The semiconductor device 100 can be used by covering the side wall 10 of the package 1A with the lid portion. Hermetic sealing may be performed by covering the side wall 10 with the lid portion in a state where the internal space of the package 1A has been subjected to nitrogen substitution.

The input matching circuits 106, the semiconductor dies 107, the output matching circuits 108, and the output capacitors 109 are provided in this order from the part 11 of the side wall 10. For example, the semiconductor dies 107 are transistors including a substrate such as Si, SiC, GaN, GaAs, or diamond, and a rear surface of the substrate is subjected to metal plating. As an example, the semiconductor dies 107 are GaN-HEMT. For example, the input matching circuits 106 and the output matching circuits 108 are parallel flat plate-type capacitors in which electrodes are provided on each of upper surfaces and lower surfaces of ceramic substrates.

The input matching circuits 106, the semiconductor dies 107, and the output matching circuits 108 have a rear surface subjected to metal plating (for example, gold plating) and are fixed to the main surface 3a of the base 3 with the joining material 47, similar to the sintering metal paste, interposed therebetween. The input matching circuits 106 are mounted on the input side of the semiconductor dies 107, and the output matching circuits 108 are mounted on the output side of the semiconductor dies 107. Respective sets of the input leads 5 and the input matching circuits 106, the input matching circuits 106 and the semiconductor dies 107, the semiconductor dies 107 and the output matching circuits 108, the output matching circuits 108 and the output capacitors 109, and the output capacitors 109 and the output leads 6 are electrically connected to each other using a plurality of bonding wires (not illustrated).

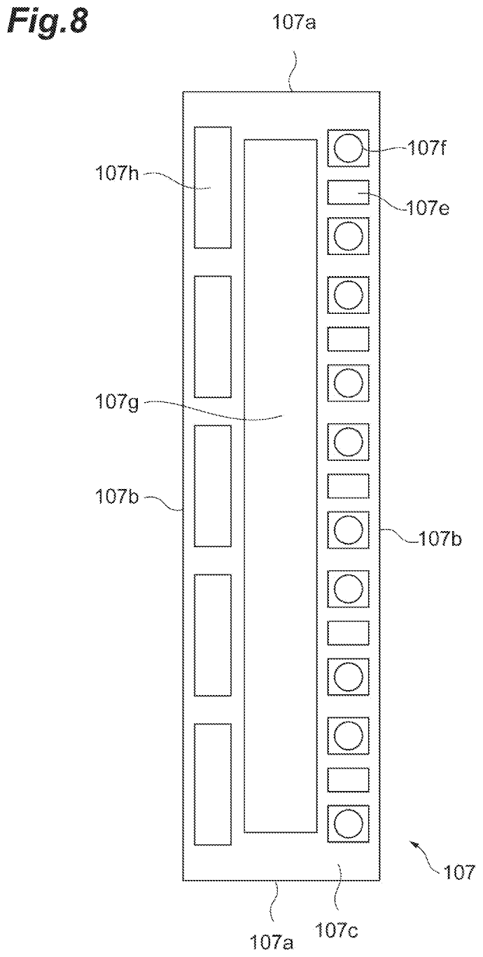

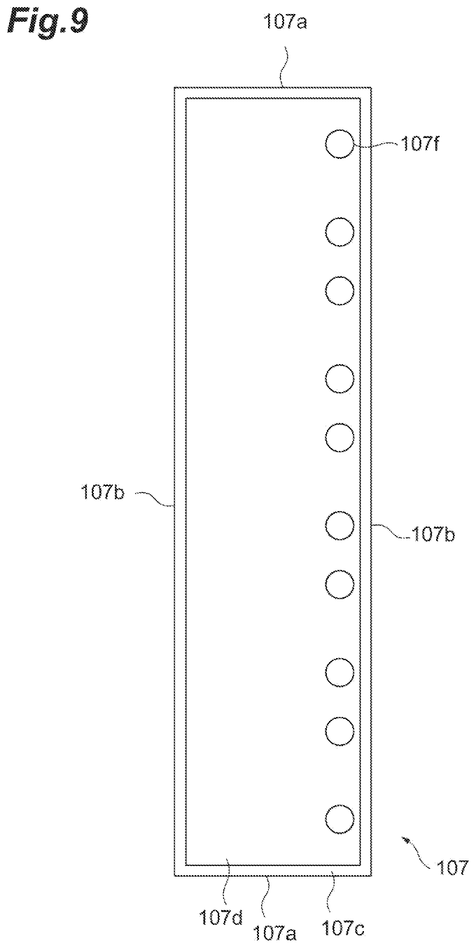

FIG. 8 is a view illustrating a front surface of the semiconductor die 107. FIG. 9 is a view illustrating a rear surface of the semiconductor die 107. As illustrated in FIGS. 8 and 9, the semiconductor die 107 has a rectangular planar shape extending in a slender manner and is defined by a pair of short sides 107a and a pair of long sides 107b. The semiconductor die 107 has a substrate 107c and source electrodes 107d provided on the rear surface of the substrate 107c. The semiconductor die 107 includes a plurality of gate electrodes 107e and source vias 107f which are arranged along the long sides 107b, an active region 107g, and drain electrodes 107h on the front surface of the substrate 107c. For example, the source electrodes 107d are subjected to gold plating, and the thicknesses of the source electrodes 107d are within a range of 5 μm to 20 μm.

The gate electrodes 107e are provided opposite to the drain electrodes 107h with the active region 107g sandwiched therebetween. The active region 107g includes drain and source fingers. The source fingers and the source electrodes 107d on the rear surface are electrically connected to each other through the source vias 107f penetrating the semiconductor dies 107. The maximum value for a current which can flow from the drain fingers to the source fingers is proportional to a gate width. Therefore, in a transistor having a large output, many drain/source fingers are provided in parallel in order to increase the gate width. Accordingly, the semiconductor die 107 has a planar shape extending in a slender manner along the long side 107b.

FIG. 7 will be referred to again. The input matching circuits 106 perform matching of impedances between the input leads 5 and the semiconductor dies 107. One ends of the input matching circuits 106 are electrically connected to the input leads 5 via bonding wires. The other ends of the input matching circuits 106 are electrically connected to the gate electrodes 107e of the semiconductor dies 107 via bonding wires (refer to FIG. 8). In this manner, the input leads 5 are electrically connected to the gate electrodes 107e of the semiconductor dies 107 via the wirings inside the package 1A.

The output matching circuits 108 adjust mismatching of the impedances between the semiconductor dies 107 and the output leads 6 and output high-frequency signals appearing in the output leads 6 with the maximum efficiency. One ends of the output matching circuits 108 are electrically connected to the drain electrodes 107h of the semiconductor dies 107 via bonding wires (refer to FIG. 8). The other ends of the output matching circuits 108 are electrically connected to the output leads 6 via bonding wires. In this manner, the output leads 6 are electrically connected to the drain electrodes 107h of the semiconductor dies 107 via the wirings inside the package 1A.

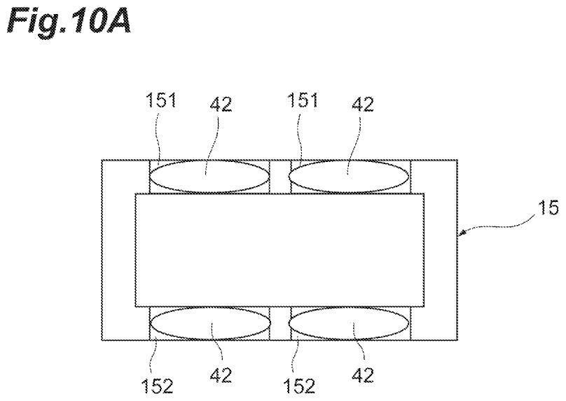

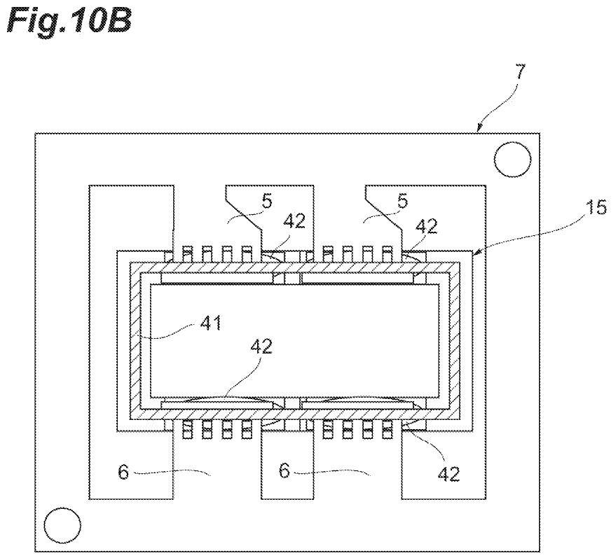

FIGS. 10A and 10B to FIGS. 16A and 16B are views for describing a method for manufacturing the package 1A and the semiconductor device 100. With reference to these diagrams, the method for manufacturing the package 1A and the semiconductor device 100 will be described.

First, a lead frame assembly is formed by bonding the first side wall portion 15 and the second side wall portion 16 to each other in a state of having a metal lead frame sandwiched therebetween. As illustrated in FIG. 10A, the adhesive 42 is applied on the bottom surfaces of the recesses 151 and 152 of the first side wall portion 15, using a dispenser. Then, as illustrated in FIG. 10B, a lead frame 7 including the input leads 5 and the output leads 6 is disposed on the first side wall portion 15 in an overlapping manner. Further, the adhesive 41 (indicated in the diagram using hatching) is applied throughout the entire circumference on the first side wall portion 15 including that on the lead frame 7 using a dispenser.

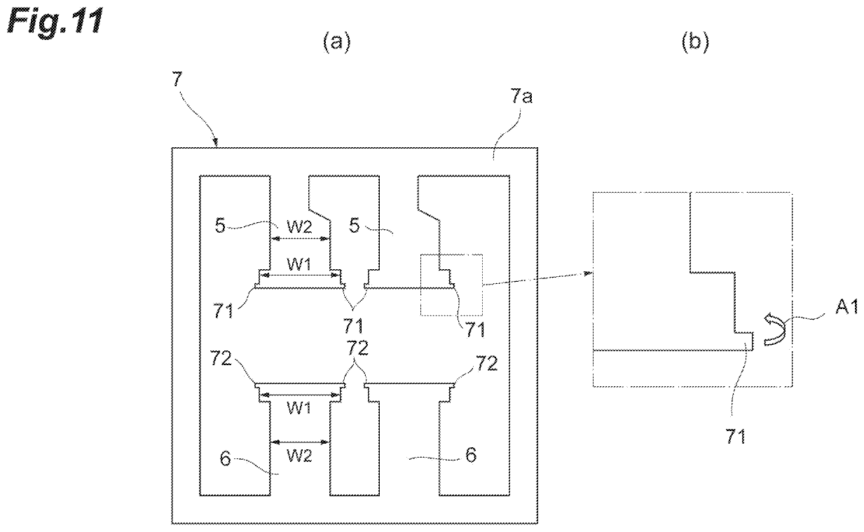

(a) portion of FIG. 11 is a plan view illustrating a specific shape of the lead frame 7. (b) portion of FIG. 11 is an enlarged view illustrating a part of the lead frame 7. As illustrated in these diagrams, the lead frame 7 of the present embodiment has a shape in which two input leads 5 and two output leads 6 are integrated using a rectangular frame portion (tie bar) 7a. The constituent material of the frame portion 7a is the same as the constituent materials of the input leads 5 and the output leads 6. For example, the lead frame 7 is formed by punching one metal plate. Widths W1 of the end portions (parts positioned on the first side wall portion 15) of the input leads 5 and the output leads 6 of the lead frame 7 are larger than widths W2 of the other parts (parts positioned outside the package 1A) of the input leads 5 and the output leads 6. Projections 71 are formed at both ends in the end portion of the input lead 5 in the width direction. Similarly, projections 72 are formed at both ends in the end portion of the output lead 6 in the width direction. The projections 71 and 72 are bent in the thickness direction of the lead frame 7 (arrow A1 in the diagram) and stand upright substantially perpendicular to an extending plane of the lead frame 7.

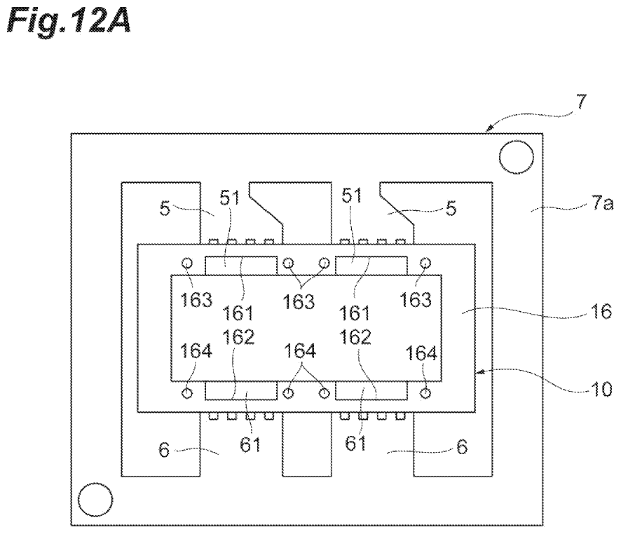

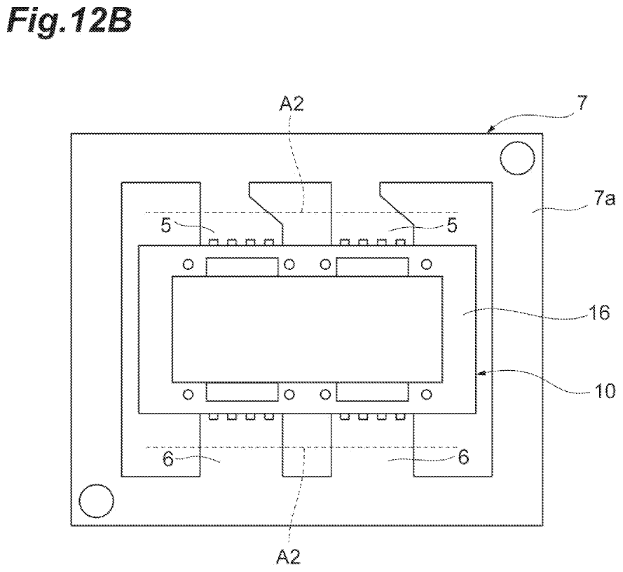

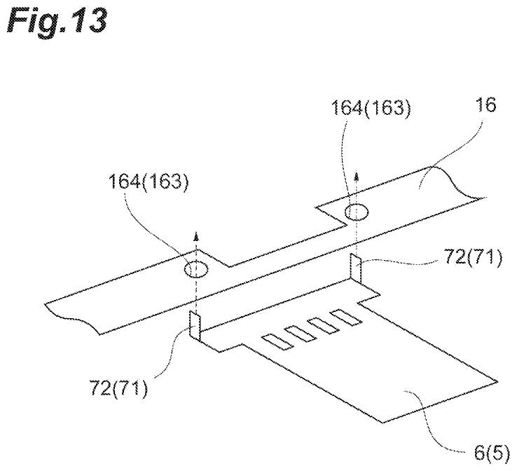

Subsequently, as illustrated in FIG. 12A, the second side wall portion 16 is disposed on the first side wall portion 15 to sandwich the lead frame 7 between the first side wall portion 15 and the second side wall portion 16. At this time, the adhesive 41 (before being cured) is interposed between the first side wall portion 15 and the second side wall portion 16. As illustrated in FIG. 13, the second side wall portion 16 is disposed on the first side wall portion 15 while the projections 71 and 72 of the lead frame 7 are respectively inserted into the holes 163 and 164 of the second side wall portion 16. When each of the projections 71 and 72 of the lead frame 7 is inserted into each of the holes 163 and 164, the position of the second side wall portion 16 with respect to the first side wall portion 15 and the lead frame 7 is determined.

Subsequently, the adhesives 41 and 42 are cured. Heat treatment is performed in two stages. Specifically, heat treatment of temporary curing is performed at a first temperature, and heat treatment of main curing is subsequently performed at a second temperature which is higher than the first temperature. For example, the first temperature is 110° C., and the second temperature is 160° C. For example, a heat treatment time at the first temperature is 30 minutes, and a heat treatment time at the second temperature is 60 minutes. The heat treatment is performed in two stages in order to ensure the reliability of curing and the strength after curing. Through this step, the first side wall portion 15, the lead frame 7, and the second side wall portion 16 are joined to each other. In place of the above heat treatment in two stages, heat treatment based on consecutive temperature profiles may be performed.

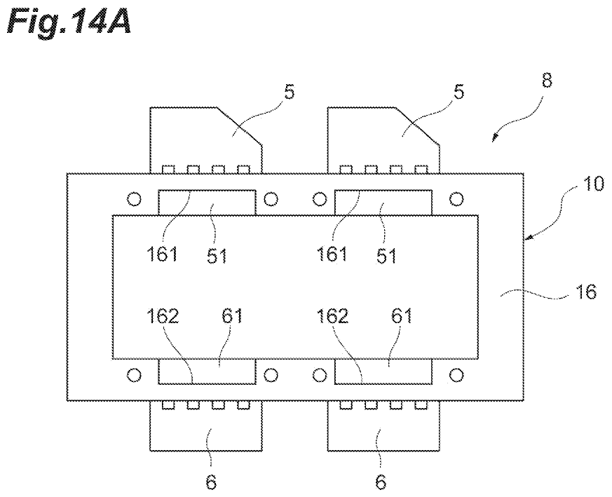

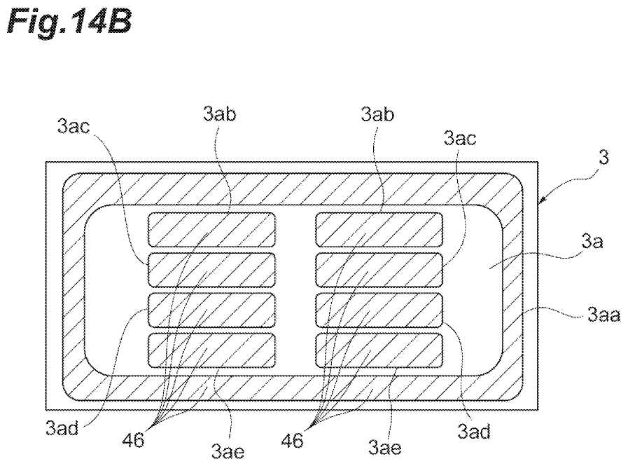

Subsequently, the lead frame 7 is cut along the cut lines A2 illustrated in FIG. 12B. Accordingly, the frame portion 7a of the lead frame 7 is cut off from the input leads 5 and the output leads 6. Through the foregoing steps, a lead frame assembly 8 illustrated in FIG. 14A is formed.

Subsequently, as illustrated in FIG. 14B, a sintering metal paste 46 is applied to a disposition region 3aa of the lead frame assembly 8 on the main surface 3a of the base 3. The sintering metal paste 46 may be further applied to each of disposition regions 3ab to 3ae of the input matching circuits 106, the semiconductor dies 107, the output matching circuits 108, and the output capacitors 109 (refer to FIG. 7 for all) on the main surface 3a of the base 3. In FIG. 14B, presence ranges of the sintering metal paste 46 are indicated using hatching. In this step, for example, the sintering metal paste 46 in each of the disposition regions 3aa to 3ae is collectively applied through screen printing.

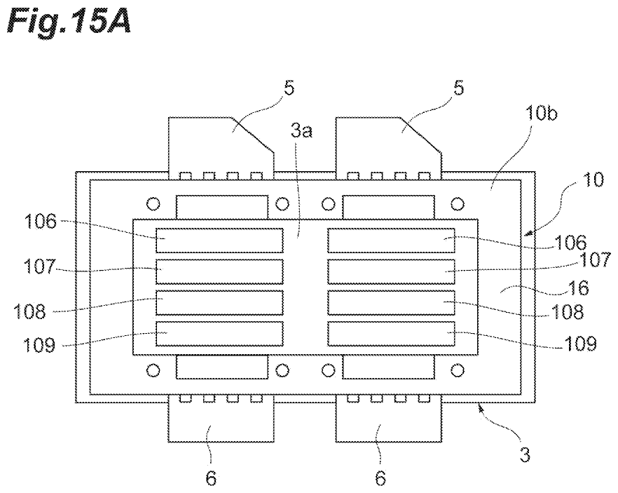

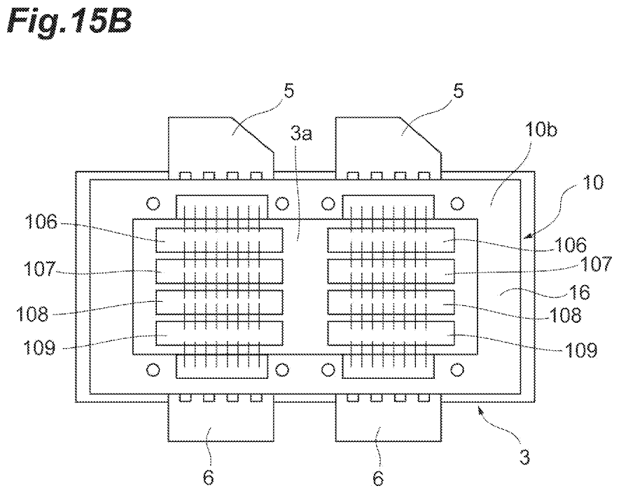

Subsequently, as illustrated in FIG. 15A, the lead frame assembly 8 is disposed on the sintering metal paste 46 applied to the disposition region 3aa. In addition, each of the input matching circuits 106, the semiconductor dies 107, the output matching circuits 108, and the output capacitors 109 is disposed on the sintering metal paste 46 applied to the disposition regions 3ab to 3ae. Then, the sintering metal paste 46 is solidified. In an example, the base 3, in which the lead frame assembly 8, the input matching circuits 106, the semiconductor dies 107, the output matching circuits 108, and the output capacitors 109 are disposed, is installed inside a heat treatment furnace. After the temperature inside the furnace is raised from room temperature to 210° C. during 60 minutes, it is maintained at the temperature for 60 minutes. Accordingly, a solvent of the sintering metal paste 46 is gasified to generate a metal body, so that the base 3 is joined to the lead frame assembly 8, the input matching circuits 106, the semiconductor dies 107, the output matching circuits 108, and the output capacitors 109 with the metal body interposed therebetween. To prevent oxidation of a metal (for example, Ag) included in the sintering metal paste 46, the inside of the heat treatment furnace may be in a nitrogen (N₂) atmosphere.

Subsequently, as illustrated in FIG. 15B, wire bonding is performed between the input leads 5, the input matching circuits 106, the semiconductor dies 107, the output matching circuits 108, the output capacitors 109, and the output leads 6. Specifically, ultrasonic bonding is performed while the base 3 and the side wall 10 are heated at approximately 200° C. This step may be performed in the atmosphere. To prevent oxidation of a metal body derived from the sintering metal paste 46, it may be performed in a nitrogen (N₂) atmosphere.

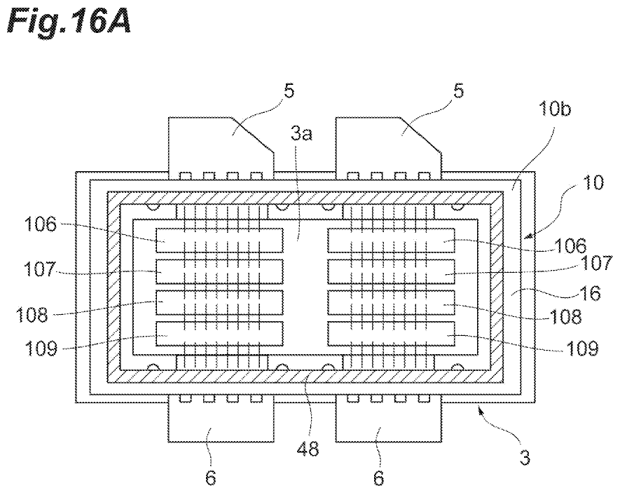

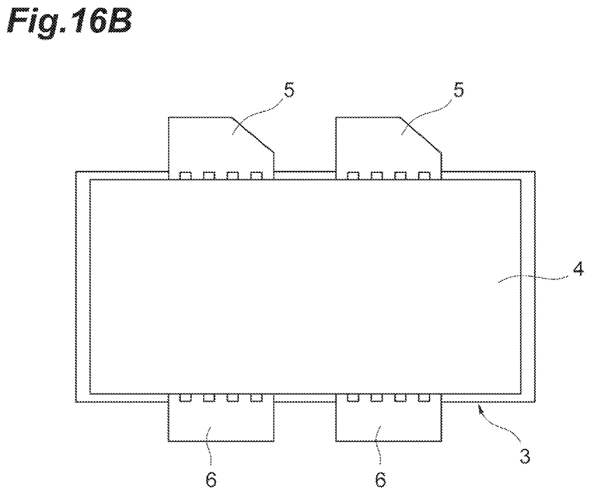

Subsequently, as illustrated in FIG. 16A, an adhesive 48 (indicated in the diagram using hatching) is applied to the upper surface 10b of the side wall 10. The adhesive 48 is a thermosetting resin and is a thermosetting epoxy resin, as an example. As illustrated in FIG. 16B, the side wall 10 is covered with a lid portion (cap) 4, and the upper surface 10b of the side wall 10 and the rear surface of the lid 4 are caused to face each other with the adhesive 48 interposed therebetween. At this time, an opening of the side wall 10 is completely covered with the lid 4. Thereafter, the inside of the package 1A is sealed by curing the adhesive 48. Specifically, similar to the adhesives 41 and 42, heat treatment in two stages is performed. The temperature and the time are similar to those of the adhesives 41 and 42. In place of the heat treatment in two stages, heat treatment based on consecutive temperature profiles may be performed. This step may be performed in the atmosphere. To eliminate moisture inside the package 1A as much as possible, it may be performed in a dried N₂ atmosphere. Through the foregoing step, the semiconductor device 100 of the present embodiment is completed.

Effects of the present embodiment described above will be described. As described above, in packages for a semiconductor device in the related art, a ceramic is often used as a material of a side wall. A ceramic side wall has higher reliability than other materials such as a resin and can firmly support a lead. However, there is a problem that it is difficult to mold a ceramic compared to other materials such as a resin. In contrast, when a resin is used as a material of the side wall, there is an advantage that molding can be performed easily and a manufacturing step can be simplified. On the other hand, in respect of strength, a resin is inferior to a ceramic. When a resin side wall has a shape similar to a ceramic side wall, such a resin side wall may not be able to support a lead firmly.

In order to solve this problem, the manufacturing method according to the present embodiment includes a step of forming the lead frame assembly 8 (FIG. 14A) in which the first side wall portion 15 made of a resin constituting a part of the side wall 10 near the main surface 3a and the second side wall portion 16 made of a resin constituting the remaining part of the side wall 10 opposite to the main surface 3a are bonded to each other in a state of having the metal lead frame 7 sandwiched therebetween, a step of applying the sintering metal paste 46 to the disposition region 3aa of the lead frame assembly 8 on the main surface 3a of the base 3 (FIG. 14B) and disposing the lead frame assembly 8 on the sintering metal paste 46 (FIG. 15A), and a step of sintering the sintering metal paste 46 between the base 3 and the lead frame assembly 8 to join the base 3 and the lead frame assembly 8 to each other. According to this method, since the lead frame 7 is sandwiched between the first side wall portion 15 and the second side wall portion 16, the input leads 5 and the output leads 6 of the lead frame 7 can be firmly supported using the resin side wall 10.

As in the present embodiment, the step of forming the lead frame assembly 8 may further include a step of bending the projections 71 and 72 formed in the lead frame 7 in the thickness direction of the lead frame 7, and a step of sandwiching the lead frame 7 between the first side wall portion 15 and the second side wall portion 16 while the projections 71 and 72 are respectively inserted into the holes 163 and 164 formed in the second side wall portion 16. Accordingly, positioning of the second side wall portion 16 with respect to the lead frame 7 can be performed easily and accurately, and bonding strength between the lead frame 7 and the second side wall portion 16 can be enhanced, so that the reliability can be improved. In the present embodiment, the holes 163 and 164 for inserting the projections 71 and 72 are formed in the second side wall portion 16. However, similar holes may also be formed in the first side wall portion 15.

As in the present embodiment, the first side wall portion 15 may have the recesses 151 for receiving the input leads 5 of the lead frame 7 and the recesses 152 for receiving the output leads 6 on a surface facing the lead frame 7. According to such a constitution, the lead frame 7 having a certain degree of thickness can be sandwiched between the first side wall portion 15 and the second side wall portion 16. In addition, positioning of the lead frame 7 and the first side wall portion 15 can be performed easily and accurately. In the present embodiment, the recesses 151 and 152 are formed in the first side wall portion 15. However, similar recessed portions may also be formed in the second side wall portion 16. Alternatively, recessed portions may be formed in both the first side wall portion 15 and the second side wall portion 16. As an example, holes for inserting the projections 71 and 72 of the lead frame 7 are formed in one side wall portion, and recessed portions for receiving the lead frame 7 are formed in the other side wall portion. In this case, positioning of the first side wall portion 15, the lead frame 7, and the second side wall portion 16 can be performed easily and accurately.

As in the present embodiment, in the step of forming the lead frame assembly 8, the first side wall portion 15, the lead frame 7, and the second side wall portion 16 may be bonded to each other using the adhesives 41 and 42 (thermosetting resins). When the sintering metal paste 46 between the lead frame assembly 8 and the base 3 is sintered, the adhesives 41 and 42 are exposed to a high temperature. When the adhesives 41 and 42 are thermosetting resins, softening of the adhesives 41 and 42 due to a high temperature can be curbed, and bonding strength can be maintained.

As in the present embodiment, in the step of applying the sintering metal paste 46 (FIG. 14B), the sintering metal paste 46 may be further applied to the disposition regions 3ab to 3ae on the main surface 3a of the base 3, and the input matching circuits 106, the semiconductor dies 107, the output matching circuits 108, and the output capacitors 109 may be disposed on the sintering metal paste 46 (FIG. 15A). In the step of sintering the sintering metal paste 46, the sintering metal paste 46 on these disposition regions 3ab to 3ae may be sintered, such that the input matching circuits 106, the semiconductor dies 107, the output matching circuits 108, and the output capacitors 109 are joined to the base 3. In this manner, the number of steps can be reduced by joining mounted components inside the package 1A to the base 3 at the same time as the lead frame assembly 8 using the sintering metal paste 46.

### First Modification Example

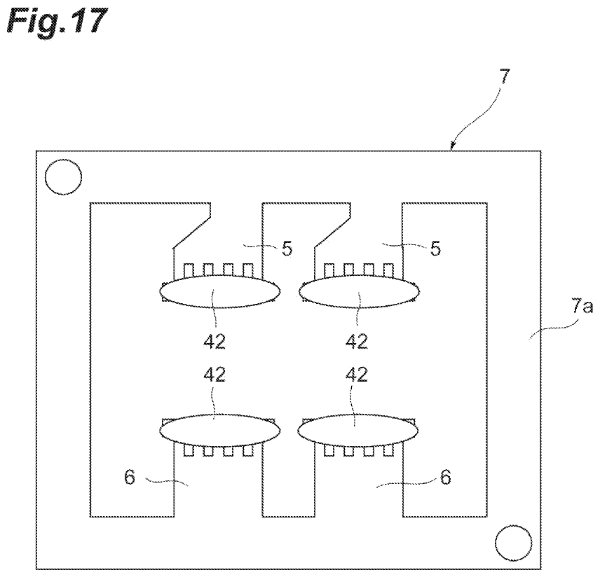

FIG. 17 is a view illustrating a step according to a first modification example of the foregoing embodiment, showing the lead frame 7 and the adhesive 42. In FIG. 10A of the foregoing embodiment, the adhesive 42 is applied to the first side wall portion 15 when the lead frame 7 is bonded to the first side wall portion 15. As illustrated in FIG. 17, the adhesive 42 in a B stage (semi-cured state) may be applied to the lead frame 7. In this manner as well, the lead frame 7 and the first side wall portion 15 can be bonded to each other easily and firmly.

### Second Modification Example

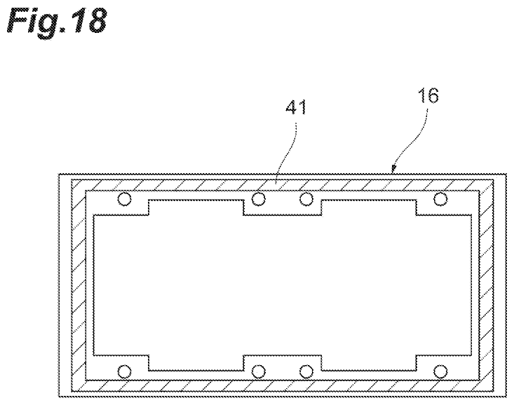

FIG. 18 is a view illustrating a step according to a second modification example of the foregoing embodiment, showing the second side wall portion 16 and the adhesive 41. In FIG. 10B of the foregoing embodiment, the adhesive 41 is applied to the first side wall portion 15 and the lead frame 7 when the second side wall portion 16 is bonded to the first side wall portion 15 and the lead frame 7. As illustrated in FIG. 18, the adhesive 41 in the B stage (semi-cured state) may be applied to the second side wall portion 16. In this manner as well, the second side wall portion 16 can be bonded to the first side wall portion 15 and the lead frame 7 easily and firmly.

### Third Modification Example

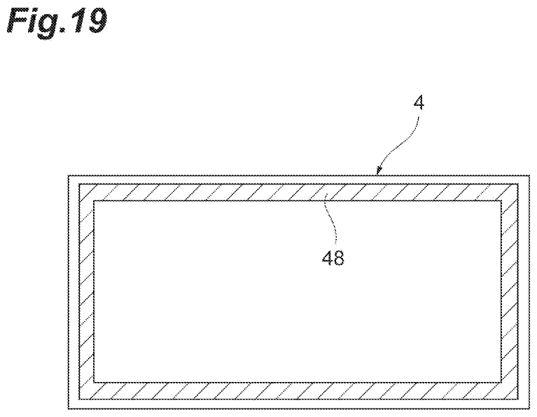

FIG. 19 is a view illustrating a step according to a third modification example of the foregoing embodiment, showing the lid 4 and the adhesive 48. In FIGS. 16A and 16B of the foregoing embodiment, the adhesive 48 is applied to the upper surface 10b when the lid 4 is bonded to the upper surface 10b of the side wall 10. As illustrated in FIG. 19, the adhesive 48 in the B stage (semi-cured state) may be applied to the rear surface of the lid 4. In this manner as well, the lid 4 and the side wall 10 can be bonded to each other easily and firmly.

### Fourth Modification Example

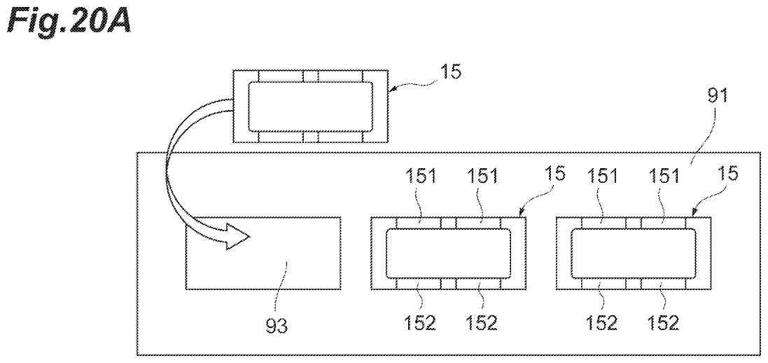

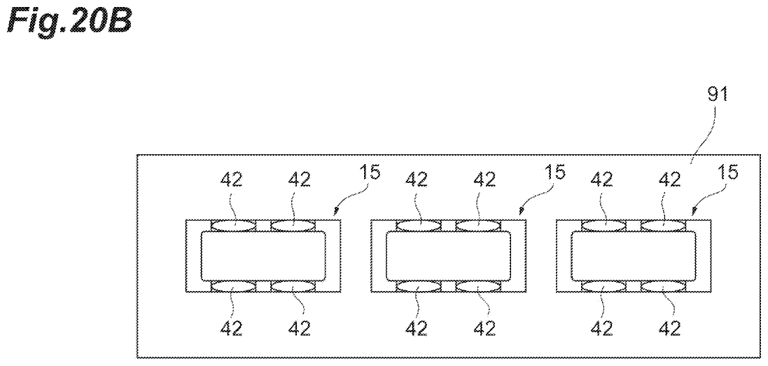

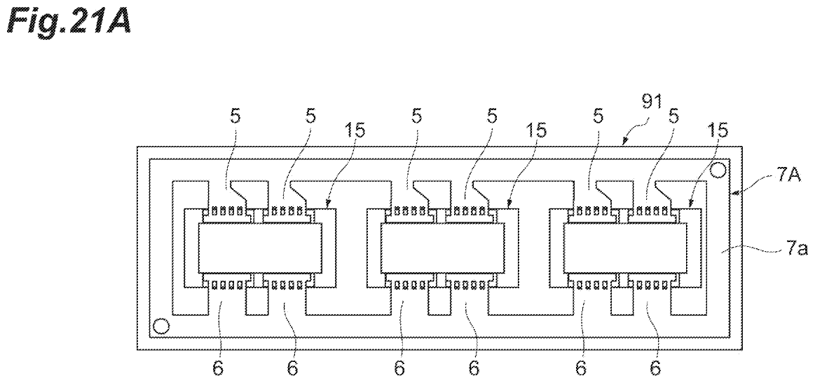

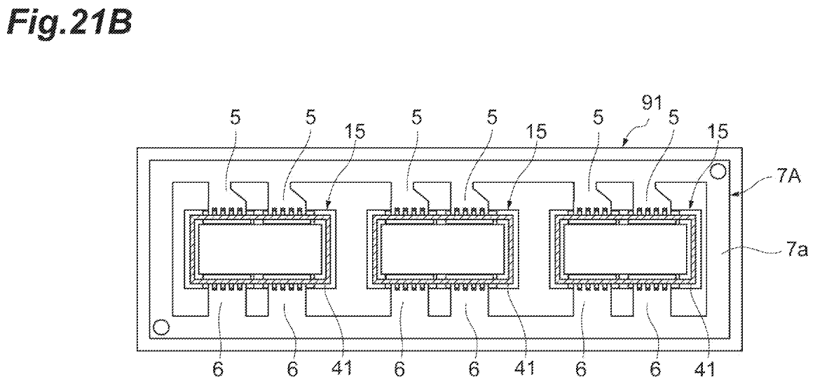

FIGS. 20A and 20B to FIGS. 26A and 26B are views illustrating each of steps in a manufacturing method according to a fourth modification example of the foregoing embodiment. In this modification example, N (N is an integer of 2 or larger, and the diagram illustrates an example of a case of N=3) semiconductor devices 100 are collectively assembled. First, as illustrated in FIG. 20A, N first side wall portions 15 are pasted in respective predetermined regions 93 arranged on a plate-shaped jig 91. Next, as illustrated in FIG. 20B, the adhesive 42 is applied to each of the recesses 151 and 152 of the first side wall portions 15. Subsequently, as illustrated in FIG. 21A, a lead frame 7A is disposed on the first side wall portions 15. The lead frame 7A of the present modification example has a configuration in which N sets of input leads 5 and N sets of output leads 6 corresponding to N semiconductor devices 100 are integrally supported by the frame portion 7a.

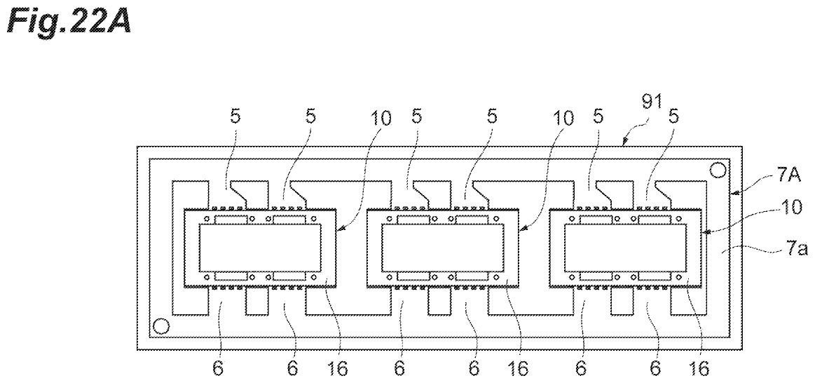

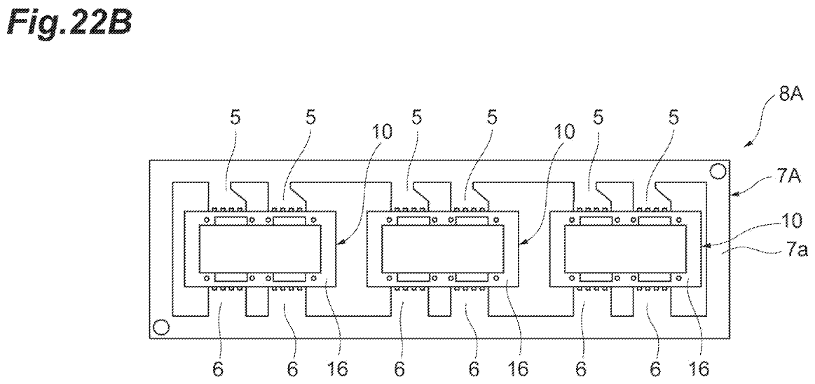

Subsequently, as illustrated in FIG. 21B, the adhesive 41 is applied throughout the entire circumference (including parts on the lead frame 7A) of each of the first side wall portions 15. As illustrated in FIG. 22A, the second side wall portion 16 is caused to overlap each of the first side wall portions 15 above thereof, and the adhesives 41 and 42 is cured in a heat treatment furnace. Each of the first side wall portions 15 is peeled off from the jig 91, thereby completing a lead frame assembly 8A (see FIG. 22B).

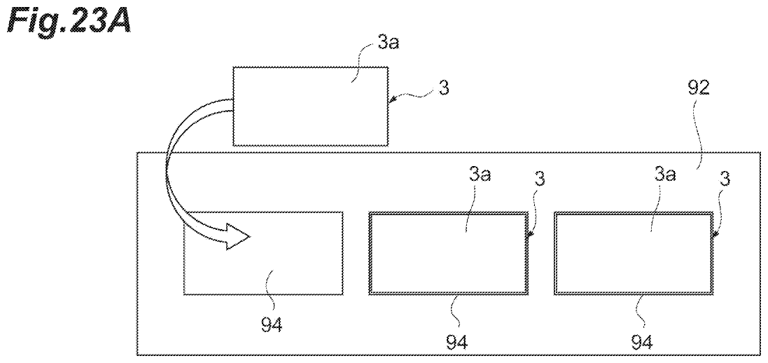

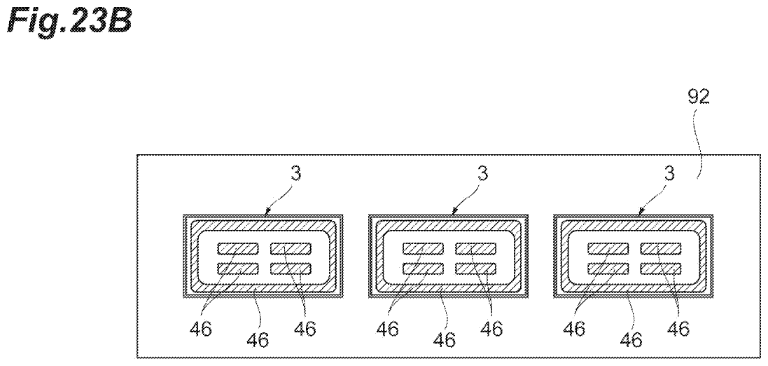

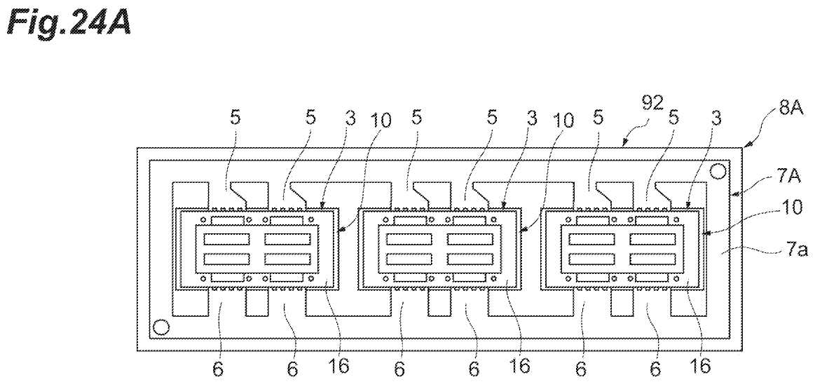

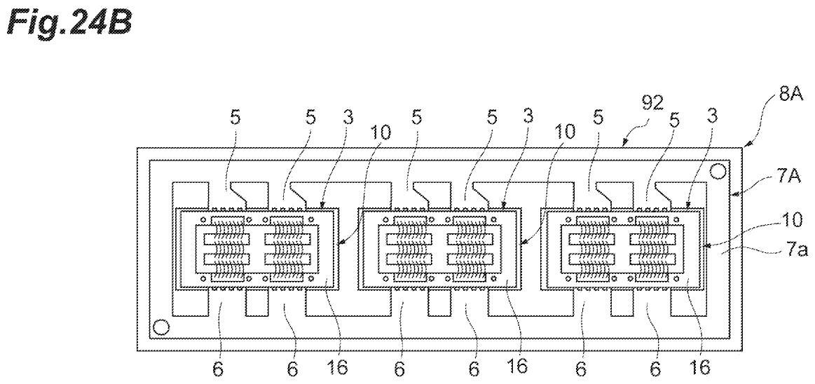

Subsequently, as illustrated in FIG. 23A, N bases 3 are respectively pasted in predetermined regions 94 arranged on a plate-shaped jig 92. As illustrated in FIG. 23B, the sintering metal paste 46 is applied on the main surface 3a of each of the bases 3. In this step, the sintering metal paste 46 is collectively applied to the N bases 3 through screen printing, for example. As illustrated in FIG. 24A, each of components (for example, the input matching circuits 106, the semiconductor dies 107, the output matching circuits 108, and the output capacitors 109 of the foregoing embodiment) to be accommodated in the lead frame assembly 8A and the package 1A is disposed on the sintering metal paste 46. The sintering metal paste 46 is sintered and solidified. Subsequently, as illustrated in FIG. 24B, wire bonding is performed between the components on the main surface 3a and between each of the components and the input leads 5 and the output leads 6.

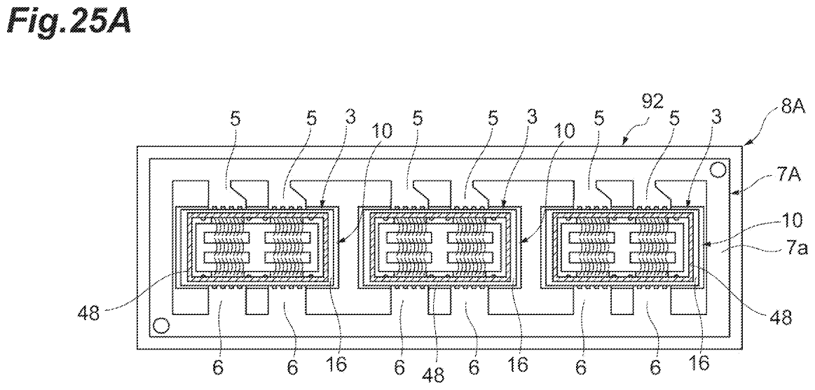

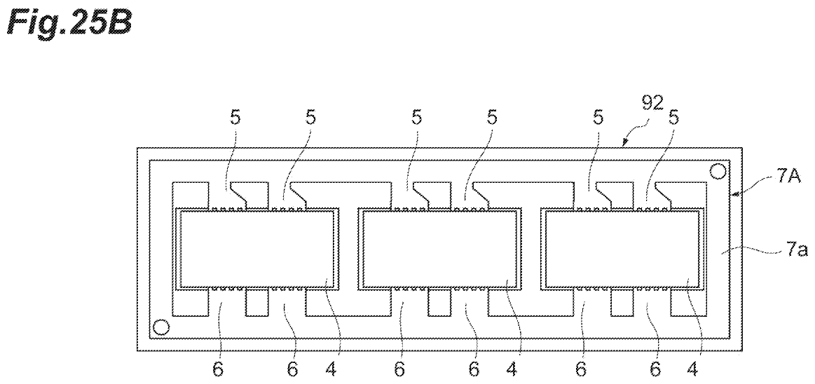

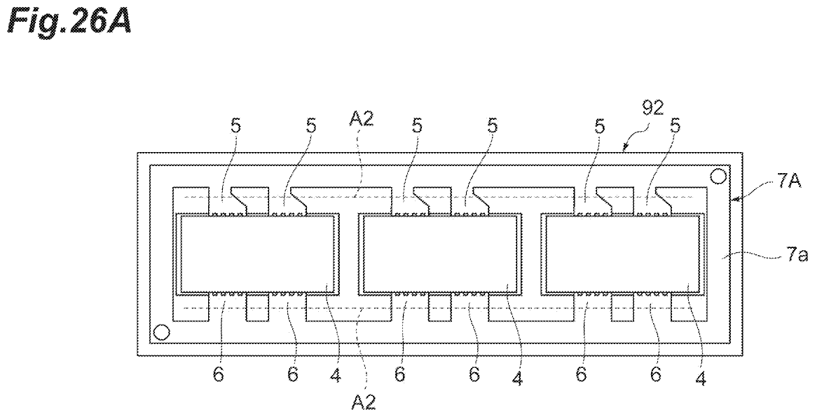

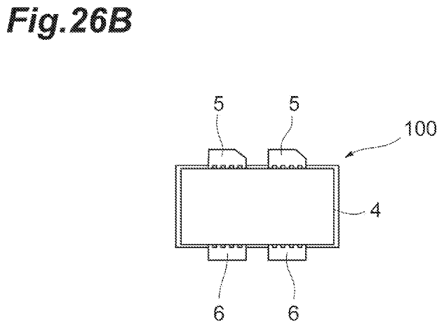

Subsequently, as illustrated in FIG. 25A, the adhesive 48 is applied to the upper surface of the side wall 10. As illustrated in FIG. 25B, the side wall 10 is covered with the lid portion (cap) 4, and the upper surface of the side wall 10 and the rear surface of the lid 4 are caused to face each other with the adhesive 48 interposed therebetween. The inside of the package 1A is sealed by curing the adhesive 48. Thereafter, the lead frame 7A is cut along the cut lines A2 indicated in FIG. 26A. Accordingly, the frame portion 7a of the lead frame 7A is cut off from the input leads 5 and the output leads 6. As illustrated in FIG. 26B, chips are individually separated from the jig 92. Through the foregoing steps, the semiconductor device 100 of the foregoing embodiment is completed.

A semiconductor package, a semiconductor device, and a method for manufacturing a semiconductor device according to the present invention are not limited to the embodiments described above, and various other modifications can be performed. For example, in the foregoing embodiment and each of the modification examples, the side wall 10 defines a single internal space. However, a side wall may define a plurality (for example, two) of internal spaces. When a side wall defines two internal spaces, it is preferable to further provide a side wall portion connecting a central portion of the part 11 in the direction D2 and a central portion of the part 12 in the same direction to each other, for example. In the foregoing embodiment, an example of the semiconductor dies 107 which are transistors serving as semiconductor elements has been described. However, the semiconductor device according to the present invention is not limited thereto, and it may include various semiconductor elements.

1-15. (canceled)

16. A method for manufacturing a semiconductor device including a metal base having a main surface to mount a semiconductor element thereon, and a side wall joined to the main surface of the metal base and surrounding the semiconductor element, the method comprising:
forming a lead frame assembly in which a first side wall portion made of a resin constituting a part of the side wall adjacent to the main surface and a second side wall portion made of a resin constituting a remaining part of the side wall opposite to the main surface are joined to each other in a state of having a metal lead frame sandwiched therebetween;
applying a sintering metal paste to a disposition region of the lead frame assembly on the main surface of the base and disposing the lead frame assembly on the sintering metal paste; and
sintering the sintering metal paste between the metal base and the lead frame assembly to join the base and the lead frame assembly to each other.

17. The method for manufacturing a semiconductor device according to claim 16,
wherein the forming of the lead frame assembly further includes,
bending a projection formed in the lead frame in a thickness direction of the lead frame, and
sandwiching the lead frame between the first side wall portion and the second side wall portion while the projection is inserted into a hole formed in the first side wall portion or the second side wall portion.

18. The method for manufacturing a semiconductor device according to claim 16, wherein at least one of the first side wall portion and the second side wall portion includes a recess configured to receive the lead frame on a surface facing the lead frame.

19. The method for manufacturing a semiconductor device according to claim 16, wherein in the forming of the lead frame assembly, the first side wall portion, the lead frame, and the second side wall portion are joined to each other using a thermosetting resin.

20. The method for manufacturing a semiconductor device according to claim 16,
wherein in the applying of the sintering metal paste, the sintering metal paste is further applied to a disposition region of the semiconductor element on the main surface of the metal base, and the semiconductor element is disposed on the sintering metal paste, and
wherein in the sintering of the sintering metal paste, the sintering metal paste between the metal base and the semiconductor element is sintered such that the metal base and the semiconductor element are joined to each other.

21. A method for manufacturing a semiconductor device including a metal base having a main surface to mount a semiconductor element thereon, and a side wall joined to the main surface of the metal base and surrounding the semiconductor element, the method comprising:
applying a sintering metal paste to a first disposition region of the lead frame assembly on the main surface of the metal base, and a second disposition region of the semiconductor element on the main surface of the metal base; and
disposing the lead frame assembly on the sintering metal paste of the first disposition region, and disposing the semiconductor element on the sintering metal paste of the second disposition region; and
sintering the sintering metal paste between the metal base and the lead frame assembly to join the metal base and the lead frame assembly to each other, and between the metal base and the semiconductor element to join the metal base and the semiconductor element to each other.

22. The method for manufacturing a semiconductor device according to claim 21, wherein applying a sintering metal paste simultaneously to both a first disposition region and the second disposition by screen printing.

23. The method for manufacturing a semiconductor device according to claim 21, wherein sintering in a heat treatment furnace with a nitrogen (N₂) atmosphere.

24. The method for manufacturing a semiconductor device according to claim 21, the method further comprising:
forming a lead frame assembly in which a metal lead frame between a first side wall and a second side wall sandwiched, and are joined to each other in a state of having a metal lead frame sandwiched therebetween;
wherein the first side wall portion made of a resin constituting a part of the side wall adjacent to the main surface, and the second side wall portion made of a resin constituting a remaining part of the side wall opposite to the main surface.

25. The method for manufacturing a semiconductor device according to claim 24, the method furthering comprising:
forming the lead frame assembly includes the process of applying the first adhesive to a part of the upper surface of the first side wall and the process of applying the first adhesive,
mounting the lead frame on the upper surface of the first side wall,
applying the second adhesive to the other parts of the upper surface of the first side wall and the upper surface of the lead frame,
mounting the second side wall on the entire circumference of the upper surface of the first side wall and the upper surface of the lead frame, and
including heat treating for the lead frame assembly.

26. The method for manufacturing a semiconductor device according to claim 25, wherein heat treating including: heat treatment and
a first heat treatment is performed at the first temperature, and a second heat treatment is performed at a second temperature higher than the first temperature.

27. The method for manufacturing a semiconductor device according to claim 21,
wherein the forming of the lead frame assembly further includes,
bending a projection formed in the lead frame in a thickness direction of the lead frame, and
sandwiching the lead frame between the first side wall portion and the second side wall portion while the projection is inserted into a hole formed in the first side wall portion or the second side wall portion.
